(19) United States
(12) Patent Application Publication
(10) Pub. No.: US 2006/0147846 A1
(43) Pub. Date: Jul. 6, 2006

(54) Method of forming photoresist pattern and semiconductor device employing the same

(75) Inventor: Kye Nam Lee, Youngin-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: DONGBUANAM SEMICONDUCTOR INC.

(21) Appl. No.: 11/320,887

(22) Filed: Dec. 30, 2005

(30) Foreign Application Priority Data
Dec. 30, 2004 (KR) 10-2004-0117154

(51) Int. Cl. G03F 7/00

(52) U.S. Cl. 430/322; 430/394

(57) ABSTRACT

A method of forming a photoresist pattern includes forming a material layer on a substrate, coating a photoresist on the material layer, and forming photoresist patterns by performing at least two times a process of exposing and developing the coated photoresist. A semiconductor device includes a material layer formed on a substrate, and photoresist patterns formed by performing two or more times an exposing and developing process on a photoresist coated on the material layer, wherein the material layer is etched using the photoresist patterns as a mask.

### BACKGROUND OF THE INVENTION

1. Field of the Invention

The present invention relates to a method of forming a photoresist pattern and a semiconductor device employing the same, and more particularly, to a method of forming a photoresist pattern using a multi exposure and a semiconductor device employing the same.

2. Description of the Related Art

Generally, lithography is a process used in semiconductor device fabrication to transfer a pattern of a mask to a photoresist formed on the surface of a substrate by the use of light.

In the lithography process, resolution is a scale defining a minimum number of micrometer in which a fine pattern may be formed. A depth of focus (DOF) is a scale defining a maximum number of micrometer in which a step range is overcome so that a valid pattern can be obtained. The resolution and the DOF are expressed as
R=k₁·λ/NA (1)
DOF=k₂·λ/(NA)² (2)

where R, λ and NA represent a limit resolution, a wavelength of light, and a numerical aperture, respectively.

In Eqs. (1) and (2), k₁ is a constant related to a process condition, such as the quality of photoresist and mask, and k₂ is an index representing how correctly a design information is transferred to a wafer. As the pattern is simpler, k₂ has a larger value.

Therefore, in order to improve the exposure process, the parameters λ and k₁ have to be small, while the parameter k₂ is large. Also, the resolution has to be low, while the DOF is large.

However, in case where the same photoresist is used in the exposure process, if the thickness of the photoresist is small, the value of k₁ decreases and the value of k₂ increases. However, since the photoresist is somewhat etched in the etching process. Therefore, since the photoresist has to be formed to more than a predetermined thickness so that it can serve as an etch stop layer, there is a limitation in increasing the processability by adjusting the thickness of the photoresist.

For this reason, in the recent semiconductor device fabrication, a deep ultraviolet (DUV) exposure apparatus using a light source with a wavelength of less than 300 nm is widely used for defining the pattern of a critical dimension (CD) to ultra-fine line of less than 100 nm.

Examples of the DUV exposure apparatus are a KrF (248 nm) excimer laser, an ArF (193 nm) excimer laser, and so on. The DUV exposure apparatus uses the light source whose wavelength is short and thus has good resolution. However, as the wavelength of the light decreases, the DOF decreases and the value of k₂ decreases due to the existence of various complex patterns caused by the formation of the ultra-fine patterns. Further, the DOF becomes relatively small.

A related art method of forming a pattern using a single exposure will be described below with reference to FIG. 1, taking an example of a process of forming a gate stack pattern.

Referring to FIG. 1(a), a gate oxide layer 12 and a gate polysilicon layer 14 are formed on a substrate 10. A photoresist 16 is formed on the gate polysilicon layer 14. Generally, a global step difference 18 exists between cell blocks or peripheral regions in the substrate 10.

Also, the photoresist 16 is coated using a spin coating process. Therefore, when the step difference 18 exists in the substrate 10, the photoresist formed at a high position is coated more thickly than the photoresist formed at a low position.

Referring to FIG. 1(b), the photoresist 16 is exposed and developed to form photoresist patterns 16a and 16b. However, since the photoresist formed at a high position is thinner than the photoresist formed at a low position, light is irradiated until the photoresist formed at the low position is completely exposed. Consequently, the photoresist is over-exposed.

Since the critical dimension D1 of the photoresist pattern 16a formed at the higher position decreases at its side due to the over exposure, it is less than the critical dimension D2 of the photoresist pattern 16b formed at the low position.

Referring to FIG. 1(c), the gate polysilicon layer 44 and the gate oxide layer are sequentially etched using the photoresist patterns 16a and 16b with different critical dimensions as an etching mask, thereby forming gate polysilicon layer patterns 14a and 14b and gate oxide layer patterns 12a and 12b are formed. Since the photoresist layer is also etched in the etching process, the photoresist patterns are modified as indicated by reference numerals 16a′ and 16b′.

Referring to FIG. 1(d), the modified photoresist patterns 16a′ and 16b′ are stripped. In this manner, using the related art patterning process, a portion of the semiconductor device 50 is completed.

However, according to the related art method of forming the pattern using the single exposure, the critical dimension D1 of the gate polysilicon layer pattern 14a formed at the high position is different from the critical dimension D2 of the gate polysilicon layer pattern 14b formed at the low position due to the difference of the critical dimensions of the photoresist patterns 16a and 16b, which is caused by the global step difference 18.

As described above, due to the global step difference 18 caused by the density difference of the photoresist between the cell blocks or the peripheral regions, the critical dimensions D1 and D2 after the exposure are different.

Specifically, in high integrated semiconductor devices having the critical dimension of less than 100 nm, the DUV exposure apparatus is inevitably used. However, since the DUV exposure apparatus has a relatively small DOF, it is impossible to overcome the global step difference 18, resulting in ununiform critical dimension.

Also, even though the surface of the wafer is well polished, the global step difference between the cell blocks or peripheral regions is formed more seriously in a process of forming multi-layer interconnections requiring more complexity and high speed. Therefore, there is a difficulty in forming fine patterns using the DUV exposure apparatus.

As described above, when the DUV exposure apparatus using the single exposure is applied, the thin photoresist has to be used because the DOF is shallow. Consequently, as the thickness of the photoresist is excessively shallow, the photoresist patterns may be collapsed.

### SUMMARY OF THE INVENTION

Accordingly, the present invention is directed to a method of forming a photoresist pattern and a semiconductor device employing the same that substantially obviate one or more problems due to limitations and disadvantages of the related art.

An object of the present invention is to provide a method of forming a photoresist pattern and a semiconductor device employing the same, capable of overcome the difference of critical dimensions between photoresist patterns, which is caused by a global step difference when ultra-fine patterns are formed using a DUV exposure apparatus.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of forming a photoresist pattern, including: forming a material layer on a substrate; coating a photoresist on the material layer; and forming photoresist patterns by performing at least two times a process of exposing and developing the coated photoresist.

In another aspect of the present invention, there is provided a method of manufacturing a semiconductor device, including: forming a material layer on a substrate; coating a photoresist on the material layer; forming photoresist patterns by performing at least two times a process of exposing and developing the coated photoresist; and etching the material layer using the photoresist patterns as a mask.

In a further another aspect of the present invention, there is provided a semiconductor device including: a material layer formed on a substrate; and photoresist patterns formed by performing two or more times an exposing and developing process on a photoresist coated on the material layer, wherein the material layer is etched using the photoresist patterns as a mask.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1(a) to 1(d) are sectional views illustrating a related art method of forming photoresist patterns using a single exposure;

FIG. 2 is a sectional view illustrating a method of forming a photoresist pattern and a semiconductor device employing the same according to a first embodiment of the present invention;

FIGS. 3 to 5 are sectional views illustrating the method of forming the photoresist pattern and the semiconductor device employing the same according to the first embodiment of the present invention;

FIG. 6 is a sectional view illustrating a method of forming a photoresist pattern and a semiconductor device employing the same according to a second embodiment of the present invention; and

FIGS. 7 to 9 are sectional views illustrating the method of forming the photoresist pattern and the semiconductor device employing the same according to the second embodiment of the present invention.

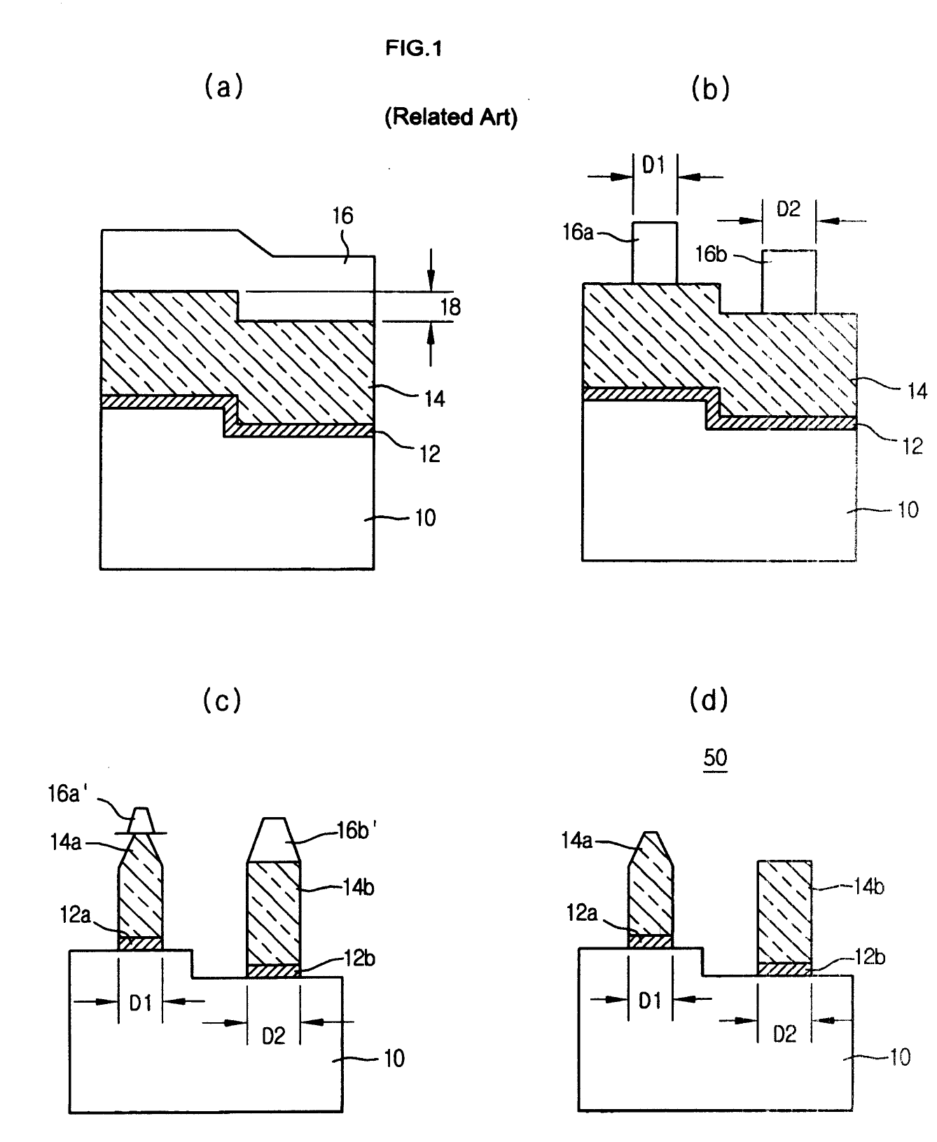

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method of forming a photoresist pattern and a semiconductor device employing the same will be described in detail with reference to the accompanying drawings.

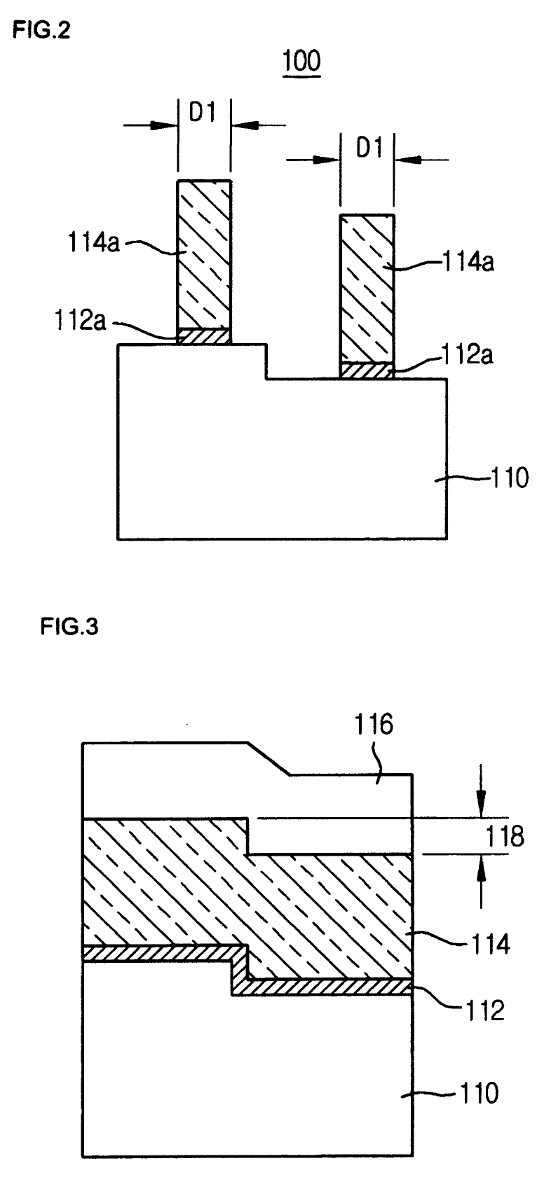

FIG. 2 is a sectional view illustrating a method of forming a photoresist pattern and a semiconductor device 100 employing the same according to a first embodiment of the present invention. In FIG. 2, only a gate oxide layer 112a and a gate 114a formed on a substrate 110 are illustrated.

The semiconductor device 100 according to the first embodiment of the present invention includes a material layer formed on the substrate 110 and a photoresist coated on the material layer. A process of exposing and developing the coated photoresist is performed at least two times to form photoresist patterns. The material layer is etched using the photoresist patterns as a mask. In this embodiment, the material layer is a gate oxide layer 112a and a gate polysilicon layer 114a.

Specifically, the photoresist patterns are formed by coating the photoresist layer on the material layer and performing at least two times a process of exposing and developing the coated photoresist up to the thickness of an optimal DOF.

According to the semiconductor device to which the method of forming the photoresist pattern according to the present invention is applied, fine critical dimension can be obtained by a multi exposure, in spite of the thickness difference of the photoresist coated on the substrate where a global step difference occurs.

Also, a small DOF that is a limitation of the DUV exposure apparatus can be solved by the multi exposure.

In addition, the DUV exposure apparatus can be applied to a thick photoresist of more than 1 μm by using the multi exposure. Consequently, the present invention can solve the problem of pattern collapse that occurs when a thin photoresist is used.

FIGS. 3 to 5 are sectional views illustrating the method of forming the photoresist pattern and the semiconductor device employing the same according to the first embodiment of the present invention.

Referring to FIG. 3, a material layer is formed on a substrate 110. In this embodiment, the material layer includes a gate oxide layer 112 and a gate polysilicon layer 114.

Then, a photoresist 116 is coated on the gate polysilicon layer 114. A soft baking process is performed on the photoresist 116 at 90-120° C. so as to evaporate an organic solvent from the coated photoresist.

Generally, the photoresist is coated in a state in which pattern step difference intensively occurs due to the formation of a unit cell, an insulation layer, etc. on the substrate 110 through predetermined processes. Therefore, a global step difference 118 exists between cell blocks or peripheral regions in the substrate 110.

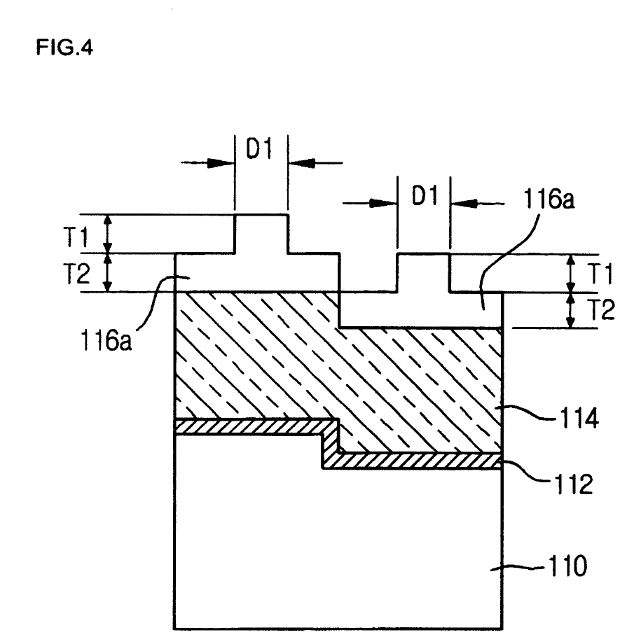

Referring to FIG. 4, a process of exposing and developing the coated photoresist 116 up to a thickness of an optimal DOF is performed at least two times to thereby form photoresist patterns. In more specifically, the photoresist 116 is primarily exposed to a thickness T1 of an optimal DOF. Then, the exposed photoresist 116 is primarily developed to form photoresist patterns 106a. Critical dimensions of the photoresist patterns 116a are equally D1, regardless of the global step difference. The primarily exposed and developed first photoresist patterns 106a are secondarily exposed up to a thickness T2 of an optimal DOF.

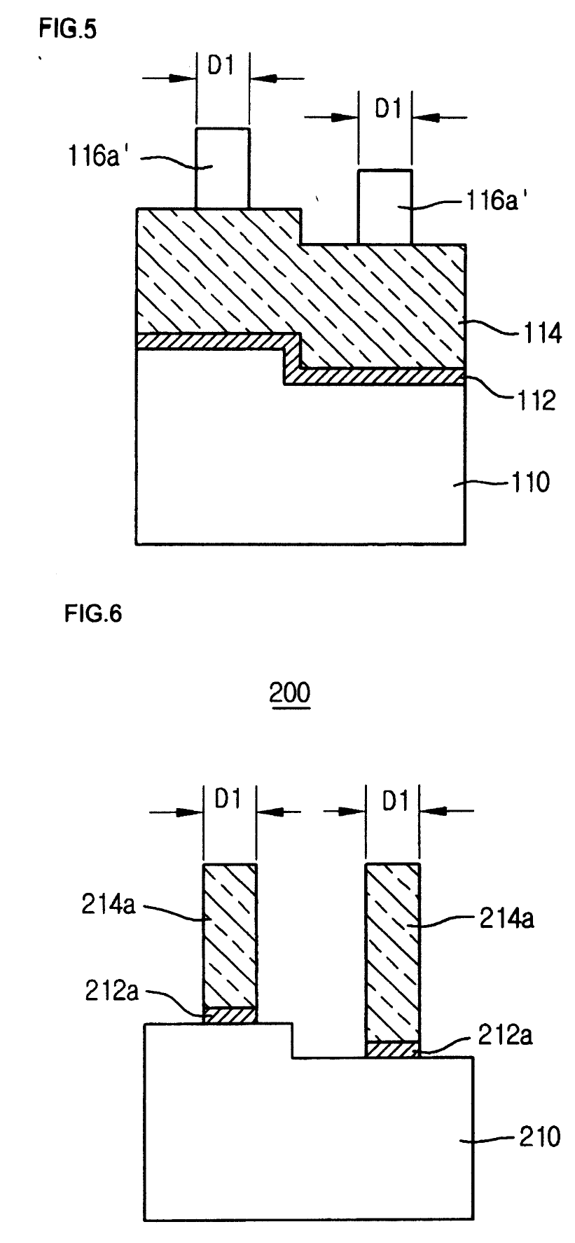

Referring to FIG. 5, the secondarily exposed photoresist patterns 106a are secondarily developed to form second photoresist patterns 106a′. Unlike the related art photoresist pattern formed using the single exposure, the photoresist 116a formed at a high position after the primary exposure process using the multi exposure has a residual photoresist. Therefore, an over exposure does not occur until the photoresist 116a formed at a low position is completely exposed. That is, the critical dimensions of the second photoresist patterns 116a′ are equally D1, regardless of the global step difference.

Then, a hard baking process is performed at 120-180° C. for about 20-30 seconds so as to increase the durability and chemical resistance of the second photoresist patterns 116a′ having on difference of the critical dimensions.

Although the two-step exposure and development processes have been described with reference to FIGS. 4 and 5, photoresist patterns having the equal critical dimensions can be formed on the substrate with the global step difference if the exposure and development are performed on a thick photoresist in multi steps.

Referring to FIG. 2, the gate polysilicon layer 114 and the gate oxide layer 112 are sequentially etched using the hard-baked second photoresist patterns 116a′ as an etching mask. Through the above procedures, the semiconductor device 100 including the gate polysilicon layer patterns 114a and the gate oxide layer patterns 112a according to the first embodiment of the present invention is completed. Thereafter, a spacer may be formed or a salicide process may be formed.

FIG. 6 is a sectional view illustrating a method of forming a photoresist pattern and a semiconductor device 200 employing the same according to a second embodiment of the present invention. In FIG. 6, only a gate oxide layer 212a and a gate 214a formed on a substrate 210 are illustrated.

The semiconductor device 200 according to the second embodiment of the present invention includes a material layer formed on the substrate 210 and a photoresist coated on the material layer. A process of exposing and developing the coated photoresist is performed at least two times to form photoresist patterns. The material layer is etched using the photoresist patterns as a mask. In this embodiment, the material layer is a gate oxide layer 212a and a gate polysilicon layer 214a.

The photoresist patterns are formed by coating the photoresist layer on the material layer and performing at least two times a process of exposing and developing the coated photoresist up to the thickness of an optimal DOF.

Specifically, after the photoresist is coated, a process of planarizing the photoresist is further performed so as to remove roughness of the surface of the photoresist.

According to the second embodiment of the present invention, in addition to the effect of the first embodiment, the roughness of the surface of the photoresist can be prevented by performing an exposure process after the coated photoresist is planarized. Therefore, the reliability of the semiconductor device having a multi-layered metal interconnection structure can be increased.

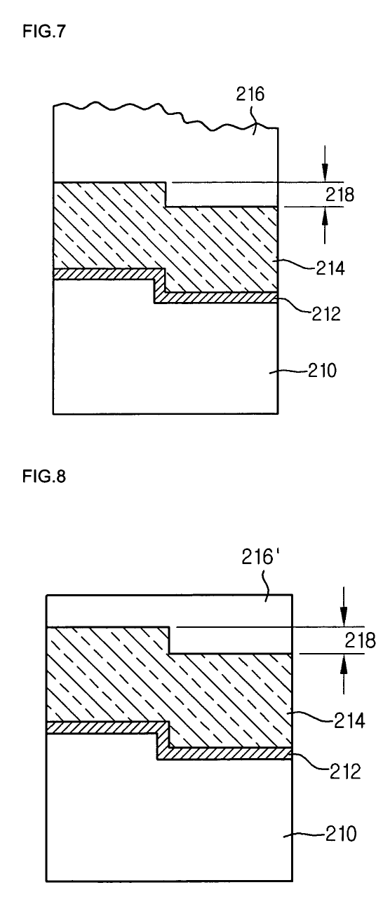

FIGS. 7 to 9 are sectional views illustrating the method of forming the photoresist pattern and the semiconductor device employing the same according to the second embodiment of the present invention.

Referring to FIG. 7, a material layer is formed on a substrate 210. In this embodiment, the material layer includes a gate oxide layer 212 and a gate polysilicon layer 214. Then, a photoresist 216 is coated on the gate polysilicon layer 214. Generally, the photoresist is coated in a state in which pattern step difference intensively occurs due to the formation of a unit cell, an insulation layer, etc. on the substrate 210 through predetermined processes. Therefore, a global step difference 218 exists between cell blocks or peripheral regions in the substrate 210.

Referring to FIG. 8, the photoresist 216 is planarized to thereby form a photoresist 216′ with no roughness. The planarized photoresist can be hardened at 110-160° C. for 20-60 seconds within a hot plate oven or a convection oven. Also, when the perfect planarization is difficult due to the large step difference of patterns, which is caused by lower metal interconnections and the like, the planarization can be perfectly achieved without formation of particles by irradiating a deep UV having a wavelength of 150-300 nm for 50-30 seconds after the hardening process.

Then, a soft baking process is performed at 90-120° C. so as to evaporate an organic solvent from the coated photoresist 216′.

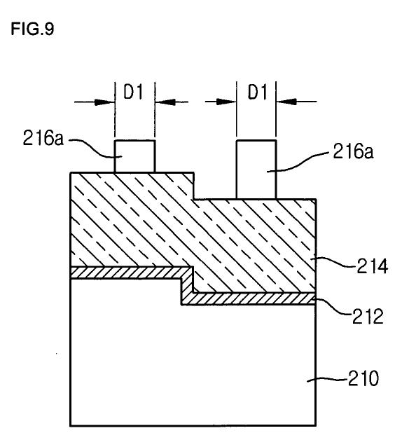

Referring to FIG. 9, the photoresist 216′ is primarily exposed to a thickness of an optimal DOF. Then, the primarily exposed photoresist 216′ is primarily developed to form photoresist patterns. Then, the primarily exposed and developed first photoresist patterns are secondarily exposed up to a thickness of an optimal DOF.

The secondarily exposed photoresist patterns are secondarily developed to form second photoresist patterns 216a. At this point, the critical dimensions of the second photoresist patterns 216a are equally D1, regardless of the roughness or global step difference of the photoresist.

Although the two-step exposure and development processes have been described with reference to FIG. 9, the present invention is not limited to them. That is, the exposure and development processes can be performed two or more times.

Referring to FIG. 6, a hard baking process is performed on the second photoresist patterns 216a. The gate polysilicon layer 214 and the gate oxide layer 212 are sequentially etched using the hard-baked second photoresist patterns 216a as an etching mask. Through the above procedures, the semiconductor device 200 including the gate polysilicon layer patterns 214a and the gate oxide layer patterns 212a according to the second embodiment of the present invention is completed. Thereafter, a spacer may be formed or a salicide process may be formed.

The present invention can be applied to methods of forming the photoresist pattern and semiconductor devices employing the same, and can solve the problems that the critical dimensions are ununiform due to the global step difference.

Also, the lithography for forming the photoresist pattern according to the present invention is not limited to the optical lithography. That is, a radiation lithography and a non-optical lithography can be used.

It will be apparent to those skilled in the art that various modifications and variations can be made in the present invention. Thus, it is intended that the present invention covers the modifications and variations of this invention provided they come within the scope of the appended claims and their equivalent.

What is claimed is:

1. A method of forming a photoresist pattern, comprising:
forming a material layer on a substrate;
coating a photoresist on the material layer; and
forming photoresist patterns by performing at least two times a process of exposing and developing the coated photoresist.

2. The method according to claim 1, wherein the material layer includes a gate polysilicon layer and a gate oxide layer.

3. The method according to claim 1, wherein the forming of the photoresist patterns includes:
primarily exposing and developing the coated photoresist to a thickness of an optimal depth of focus (DOF); and
secondarily exposing and developing the primarily exposed and developed photoresist to a thickness of an optimal DOF.

4. The method according to claim 1, wherein the exposing and developing process is performed at two or more times until the coated photoresist is completely exposed.

5. The method according to claim 1, wherein the substrate has a global step difference between cell blocks or peripheral regions.

6. The method according to claim 1, further comprising a hard baking process of performing a thermal treatment on the photoresist patterns.

7. The method according to claim 1, further comprising planarizing the coated photoresist.

8. The method according to claim 7, wherein the planarization of the photoresist includes hardening the photoresist within a hot plate oven or a convection oven.

9. The method according to claim 8, further comprising irradiating an ultraviolet (UV) having a wavelength of 150-300 nm after the hardening of the photoresist.

10. A method of manufacturing a semiconductor device, comprising:
forming a material layer on a substrate;
coating a photoresist on the material layer;
forming photoresist patterns by performing at least two times a process of exposing and developing the coated photoresist; and
etching the material layer using the photoresist patterns as a mask.

11. The method according to claim 10, wherein the material layer includes a gate oxide layer and a gate polysilicon layer.

12. The method according to claim 10, wherein the forming of the photoresist patterns includes:
primarily exposing and developing the coated photoresist to a thickness of an optimal DOF; and
secondarily exposing and developing the primarily exposed and developed photoresist to a thickness of an optimal DOF.

13. The method according to claim 10, wherein the exposing and developing process is performed at two or more times until the coated photoresist is completely exposed.

14. The method according to claim 10, wherein the substrate has a global step difference between cell blocks or peripheral regions.

15. The method according to claim 10, wherein the etching process is performed using a reactive ion etching (RIE).

16. The method according to claim 10, further comprising planarizing the coated photoresist.

17. The method according to claim 16, wherein the planarization of the photoresist includes hardening the photoresist within a hot plate oven or a convection oven.

18. The method according to claim 17, wherein the hardening process includes irradiating an ultraviolet (UV) having a wavelength of 150-300 nm.

19. A semiconductor device comprising:
a material layer formed on a substrate; and
photoresist patterns formed by performing two or more times an exposing and developing process on a photoresist coated on the material layer, wherein the material layer is etched using the photoresist patterns as a mask.

20. The semiconductor device according to claim 19, wherein the photoresist patterns are formed by primarily exposing and developing the coated photoresist to a thickness of an optimal DOF, and secondarily exposing and developing the primarily exposed and developed photoresist to a thickness of an optimal DOF.
